(19) United States
(12) Patent Application Publication
(10) Pub. No.: US 2025/0374605 A1
(43) Pub. Date: Dec. 4, 2025

(54) GATE-ALL-AROUND DEVICE STRUCTURE

(71) Applicant: Taiwan Semiconductor Manufacturing Company, Ltd., Hsinchu (TW)

(72) Inventors: Wen-Kai Lin, Hsinchu (TW); Ya-Wen Zhang, New Taipei City (TW); Cheng-Hsuan Chiang, Hsinchu City (TW); Yi-Yun Tsai, Hsinchu (TW); Che-Hao Chang, Hsinchu City (TW); Tai-Chun Huang, Hsin-Chu City (TW); Tze-Liang Lee, Hsinchu (TW)

(21) Appl. No.: 18/827,267

(22) Filed: Sep. 6, 2024

Related U.S. Application Data
(60) Provisional application No. 63/655,455, filed on Jun. 3, 2024.

(51) Int. Cl. H01L 29/423; H01L 21/8234; H01L 27/088; H01L 29/06; H01L 29/66; H01L 29/775; H01L 29/786

(52) U.S. Cl. CPC H10D 30/6735; H10D 30/014; H10D 30/43; H10D 30/6757; H10D 62/121; H10D 64/017; H10D 84/013; H10D 84/0151; H10D 84/038; H10D 84/83

(57) ABSTRACT

A semiconductor structure according to the present disclosure includes a base fin over a substrate and comprising a first channel region, a second channel region, and a source/drain region between the first channel region and the second channel region, a first plurality of nanostructures disposed over the first channel region, a second plurality of nanostructures disposed over the second channel region, a first plurality of inner spacer features interleaving the first plurality of nanostructures, a second plurality of inner spacer features interleaving the second plurality of nanostructures, a bottom epitaxial layer over the source/drain region, a bottom isolation layer over the bottom epitaxial layer such that the bottom isolation layer interfaces a bottommost one of the first plurality of inner spacer features and a bottommost one of the second plurality of inner spacer features, and a source/drain feature disposed over the bottom isolation layer.

### PRIORITY DATA

This application claims priority to U.S. Provisional Patent Application Ser. No. 63/655,455, filed Jun. 3, 2024, the entirety of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Gate-all-around (GAA) transistors are examples of multi-gate devices that have become popular and promising candidates for high performance and low leakage applications. A GAA transistor has a gate structure that can extend, partially or fully, around a channel region to provide access to the channel region on two or more sides. Because its gate structure surrounds the channel regions, a GAA transistor may also be referred to as a surrounding gate transistor (SGT) or a multi-bridge-channel (MBC) transistor.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor device, according to one or more aspects of the present disclosure.

FIGS. 2-29 illustrate fragmentary cross-sectional views of a work-in-progress (WIP) structure during a fabrication process according to the method of FIG. 1, according to one or more aspects of the present disclosure.

FIG. 30 illustrates an enlarged cross-sectional view of an inner spacer feature in FIG. 28, according to one or more aspects of the present disclosure.

FIG. 31 illustrates an enlarged cross-sectional view of an inner spacer feature in FIG. 29, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. As used herein, a source/drain region, or “S/D region,” may refer to a region that provides a source and/or drain for one or multiple devices. It may also refer to a source or a drain of one or multiple devices.

The present disclosure is generally related to GAA transistors and fabrication methods thereof. GAA transistors may be fabricated using a replacement gate process, where a dummy gate stack is formed first as a placeholder and is subsequently replaced with a functional gate structure. In some replacement gate processes, sacrificial materials among nanostructures of the GAA transistor are removed after epitaxial source/drain features are formed. During the removal of the sacrificial materials, inner spacer features function to contain the etching process to define a profile of the gate structure and to protect the epitaxial source/drain features from being etched. When etching selectivity between the inner spacer features and the sacrificial materials is less than satisfactory, the profile of the gate structure may be inconsistent and the epitaxial source/drain features may be damaged.

The present disclosure provides methods for forming a GAA transistor. In an example process, a fin-shaped structure with channel layers and sacrificial layers is formed over a substrate. After formation of a dummy gate stack over a channel region of the fin-shaped structure, at least one gate spacer is formed over the dummy gate stack. Source/drain regions of the fin-shaped structure recessed. The sacrificial layers are selectively removed to release the channel layers as channel members. A dielectric dummy layer is then deposited to wrap around each of the channel members. The dielectric dummy layer is then selectively and partially recessed to form inner spacer recesses between the plurality of channel members. More than one inner spacer layer are sequentially deposited over the inner spacer recesses. The innermost inner spacer layer may include less oxygen to be more etch resistant than an outer inner spacer layer. The deposited inner spacer layers are etched back to form inner spacer features. After the inner spacer features are formed, a bottom epitaxial layer is deposited in the source/drain recess until its top surface is about level with a bottom surface of the bottommost inner spacer features. A bottom isolation layer is then deposited over the bottom epitaxial layer to interface the sidewalls of the bottommost inner spacer features. After the bottom isolation layer is formed, source/drain features are formed over the source/drain recesses. The bottommost inner spacer features and the bottom isolation layer work in synergy to prevent leakage from the source/drain feature to the substrate. After selective removal of the dummy gate stack, the dummy layer is selectively removed to release the channel members again. A gate structure is then formed to wrap around each of the channel members.

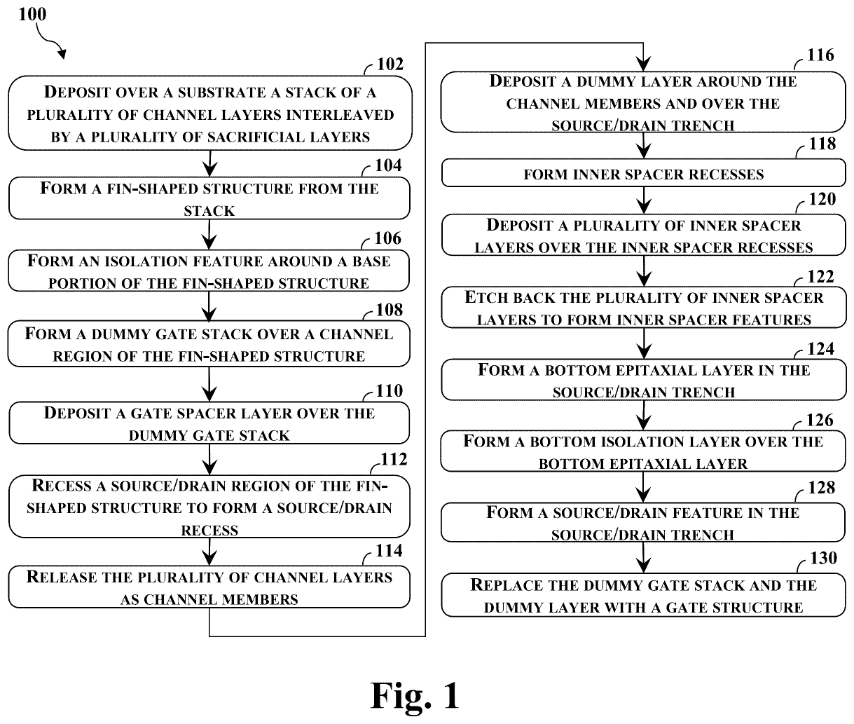

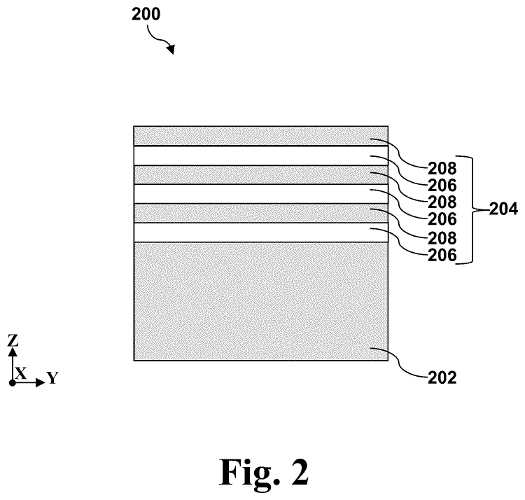

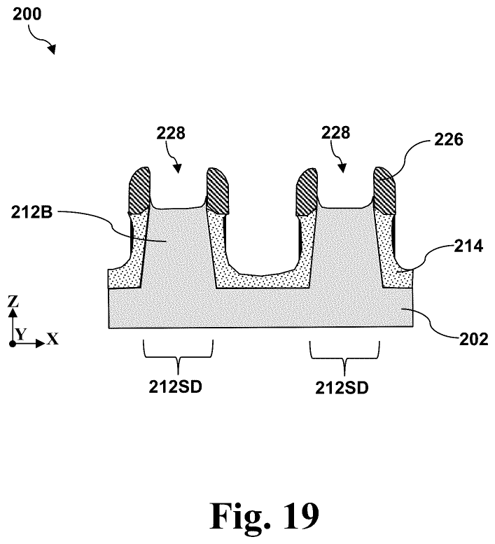

The various aspects of the present disclosure will now be described in more detail with reference to the figures. In that regard, FIG. 1 is a flowchart illustrating method 100 of forming a semiconductor structure from a work-in-progress (WIP) structure according to embodiments of the present disclosure. Method 100 is merely an example and is not intended to limit the present disclosure to what is explicitly illustrated in method 100. Additional steps can be provided before, during and after method 100, and some steps described can be replaced, eliminated, or moved around for additional embodiments of the method. Not all steps are described herein in detail for reasons of simplicity. Method 100 is described below in conjunction with FIG. 2-29, which are fragmentary cross-sectional views of a WIP structure 200 at different stages of fabrication according to embodiments of the method 100 in FIG. 1. Because the WIP structure 200 will be fabricated into a semiconductor structure or a semiconductor device, the WIP structure 200 may be referred to herein as a semiconductor structure 200 or a semiconductor device 200 as the context requires. For avoidance of doubts, the X, Y and Z directions in FIGS. 2-29 are perpendicular to one another. Throughout the present disclosure, unless expressly described otherwise, like reference numerals denote like features or steps.

Referring to FIGS. 1 and 2, method 100 includes a block 102 where a stack 204 of alternating semiconductor layers is formed over the WIP structure 200. As shown in FIG. 2, the WIP structure 200 includes a substrate 202. In some embodiments, the substrate 202 may be a semiconductor substrate such as a silicon (Si) substrate. The substrate 202 may include various doping configurations depending on design requirements as is known in the art. In embodiments where the semiconductor device is p-type, an n-type doping profile (i.e., an n-type well or n-well) may be formed on the substrate 202. In some implementations, the n-type dopant for forming the n-type well may include phosphorus (P), arsenic (As), or antimony (Sb). In embodiments where the semiconductor device is n-type, a p-type doping profile (i.e., a p-type well or p-well) may be formed on the substrate 202. In some implementations, the p-type dopant for forming the p-type well may include boron (B) or gallium (Ga). The suitable doping may include ion implantation of dopants and/or diffusion processes. The substrate 202 may also include other semiconductors such as germanium (Ge), silicon carbide (SiC), silicon germanium (SiGe), germanium tin (GeSn), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features.

In some embodiments, the stack 204 over the substrate 202 includes channel layers 208 of a first semiconductor composition interleaved by sacrificial layers 206 of a second semiconductor composition. It can also be said that the sacrificial layers 206 are interleaved by the channel layers 208. The first and second semiconductor composition may be different. In some embodiments, the sacrificial layers 206 include silicon germanium (SiGe) or germanium tin (GeSn) and the channel layers 208 include silicon (Si). It is noted that three (3) layers of the sacrificial layers 206 and three (3) layers of the channel layers 208 are alternately arranged as illustrated in FIG. 2, which is for illustrative purposes only and not intended to be limiting beyond what is specifically recited in the claims. It can be appreciated that any number of epitaxial layers may be formed in the stack 204. The number of layers depends on the desired number of channels members for the semiconductor device 200. In some embodiments, the number of channel layers 208 is between 2 and 10.

The sacrificial layers 206 and channel layers 208 in the stack 204 may be deposited using a molecular beam epitaxy (MBE) process, a vapor phase deposition (VPE) process, and/or other suitable epitaxial growth processes. As stated above, in at least some examples, the sacrificial layers 206 include an epitaxially grown silicon germanium (SiGe) layer and the channel layers 208 include an epitaxially grown silicon (Si) layer. In some embodiments, the sacrificial layers 206 and the channel layers 208 are substantially dopant-free (i.e., having an extrinsic dopant concentration from about 0 atoms/cm³ to about 1×10¹⁷ atoms/cm³), where for example, no intentional doping is performed during the epitaxial growth processes for the stack 204.

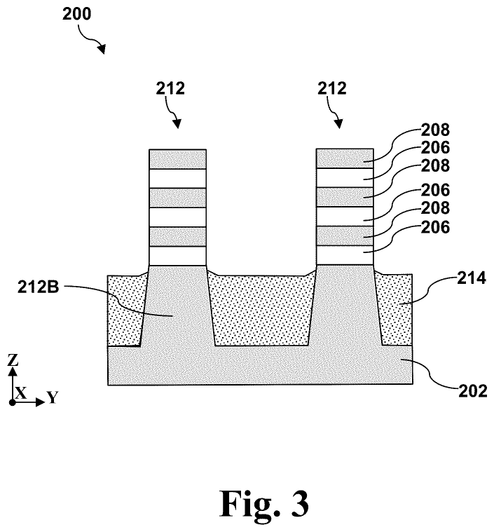

Referring to FIGS. 1 and 3, method 100 includes a block 104 where a fin-shaped structure 212 is formed from the stack 204 and the substrate 202. To pattern the stack 204, a hard mask layer may be deposited over the stack 204 to form an etch mask. The hard mask layer may be a single layer or a multi-layer. For example, the hard mask layer may include a pad oxide layer and a pad nitride layer disposed over the pad oxide layer. The fin-shaped structure 212 may be patterned from the stack 204 and the substrate 202 using a lithography process and an etch process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etching (e.g., RIE etching), wet etching, and/or other etching methods. As shown in FIG. 3, the etch process at block 104 forms trenches extending vertically through the stack 204 and a portion of the substrate 202. The trenches define the fin-shaped structures 212. In some implementations, double-patterning or multi-patterning processes may be used to define fin-shaped structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shaped structure 212 by etching the stack 204 and a portion of the substrate 202. As shown in FIG. 3, the fin-shaped structure 212 that includes the sacrificial layers 206 and the channel layers 208 extends vertically along the Z direction and lengthwise along the X direction. As shown in FIG. 3, the fin-shaped structure 212 includes a base fin structure 212B patterned from the substrate 202 and the patterned stack 204 disposed directly over the base fin structure 212B.

Referring to FIGS. 1 and 3, method 100 includes a block 106 where an isolation feature 214 is formed around a base fin structure 212B of the fin-shaped structures 212. The isolation feature 214 interfaces sidewalls of the base fin structure 212B. In some embodiments, the isolation feature 214 may be formed in the trenches to isolate the fin-shaped structures 212 from a neighboring fin-shaped structure. The isolation feature 214 may also be referred to as a shallow trench isolation (STI) feature 214. By way of example, in some embodiments, a dielectric layer is first deposited over the substrate 202, filling the trenches with the dielectric layer. In some embodiments, the dielectric layer may include silicon oxide, silicon oxynitride, fluorine-doped silicate glass (FSG), a low-k dielectric, combinations thereof, and/or other suitable materials. In various examples, the dielectric layer may be deposited by a CVD process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the STI feature 214 shown in FIG. 3. The fin-shaped structure 212 rises above the STI feature 214 after the recessing, while the base fin structure 212B is embedded or buried in the isolation feature 214.

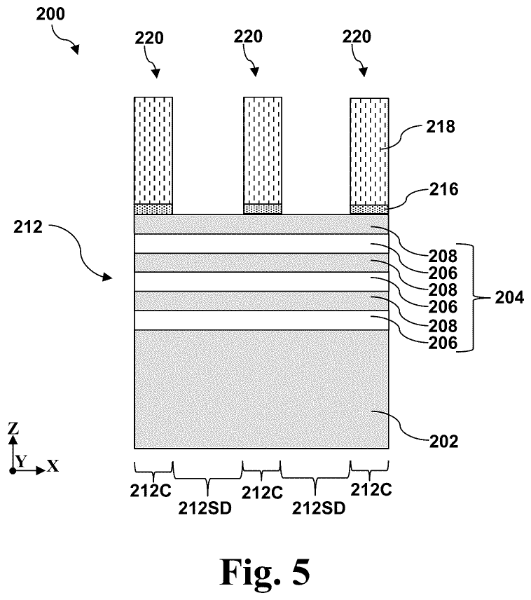

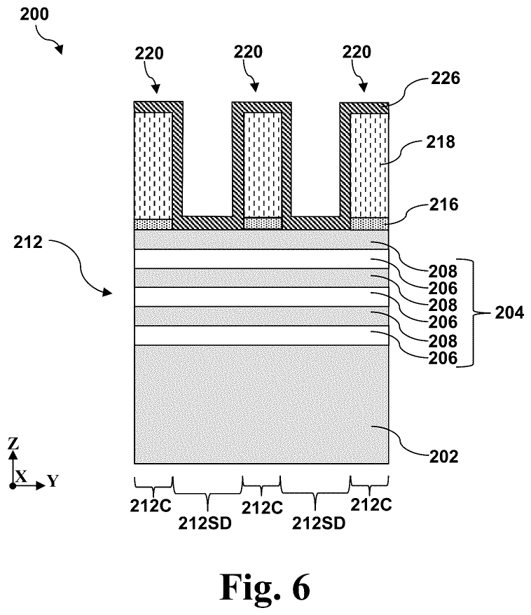

Referring to FIGS. 1, 4 and 5, method 100 includes a block 108 where a dummy gate stack 220 is formed over a channel region 212C of the fin-shaped structure 212. The dummy gate stack 220 serves as a placeholder to undergo various processes and is to be removed and replaced by a functional gate structure. Other processes and configuration are possible. In some embodiments illustrated in FIG. 5, the dummy gate stack 220 is formed over the fin-shaped structure 212 and the fin-shaped structure 212 may be divided into channel regions 212C underlying the dummy gate stacks 220 and source/drain regions 212SD that do not underlie the dummy gate stacks 220. The channel regions 212C are adjacent to the source/drain regions 212SD. As shown in FIG. 6, the channel region 212C is disposed between two source/drain regions 212SD along the X direction.

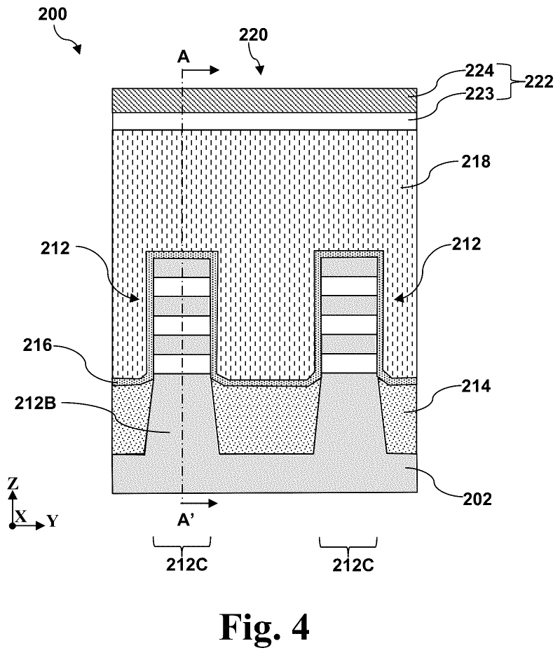

The formation of the dummy gate stack 220 may include deposition of layers in the dummy gate stack 220 and patterning of these layers. Referring to FIG. 4, a dummy dielectric layer 216, a dummy electrode layer 218, and a gate-top hard mask layer 222 may be blanketly deposited over the WIP structure 200. The dummy dielectric layer 216 may be formed on the fin-shaped structure 212 using a chemical vapor deposition (CVD) process, an ALD process, an oxygen plasma oxidation process, or other suitable processes. In the depicted embodiment, the dummy dielectric layer 216 is formed using an oxygen plasma oxidation process that substantially oxidizes the semiconductor liner 207 to form the dummy dielectric layer 216. In some instances, the dummy dielectric layer 216 may include silicon oxide. Thereafter, the dummy electrode layer 218 may be deposited over the dummy dielectric layer 216 using a CVD process, an ALD process, or other suitable processes. In some instances, the dummy electrode layer 218 may include polysilicon. For patterning purposes, the gate-top hard mask layer 222 may be deposited on the dummy electrode layer 218 using a CVD process, an ALD process, or other suitable processes. The gate-top hard mask layer 222, the dummy electrode layer 218 and the dummy dielectric layer 216 may then be patterned to form the dummy gate stack 220, as shown in FIG. 5. For example, the patterning process may include a lithography process (e.g., photolithography or e-beam lithography) and an etching process. The lithography process may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The photolithography process forms a patterned photoresist layer. The patterned photoresist layer is then applied as an etch mask in the etching process to pattern the gate-top hard mask layer 222, the dummy electrode layer 218 and the dummy dielectric layer 216. In some embodiments, the etching process may include dry etching (e.g., RIE etching), wet etching, and/or other etching methods. In some embodiments, the gate-top hard mask layer 222 may include a silicon oxide layer 223 and a silicon nitride layer 224 over the silicon oxide layer 223. As shown in FIG. 5, the dummy gate stack 220 is patterned such that it is only disposed over the channel region 212C, not disposed over the source/drain region 212SD.

Referring to FIGS. 1 and 6, method 100 includes a block 110 where a gate spacer layer 226 is deposited over the WIP structure 200, including over the dummy gate stack 220. In some embodiments, the gate spacer layer 226 is deposited conformally over the WIP structure 200, including over top surfaces and sidewalls of the dummy gate stack 220. The term “conformally” may be used herein for ease of description of a layer having substantially uniform thickness over various regions. The gate spacer layer 226 may be a single layer or a multi-layer. The at least one layer in the gate spacer layer 226 may include silicon carbonitride, silicon oxycarbide, silicon oxycarbonitride, or silicon nitride. The gate spacer layer 226 may be deposited over the dummy gate stack 220 using processes such as, a CVD process, a subatmospheric CVD (SACVD) process, an ALD process, or other suitable process.

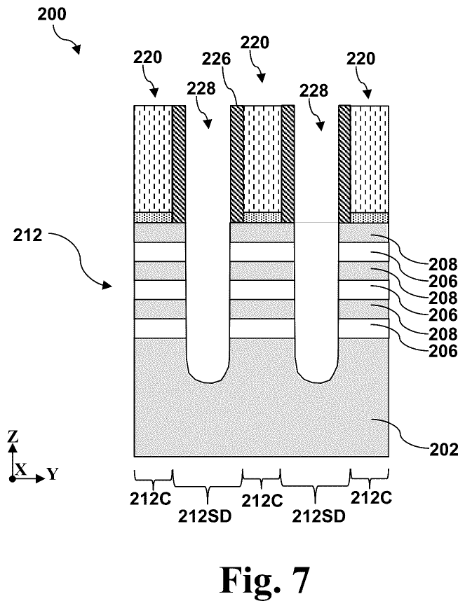

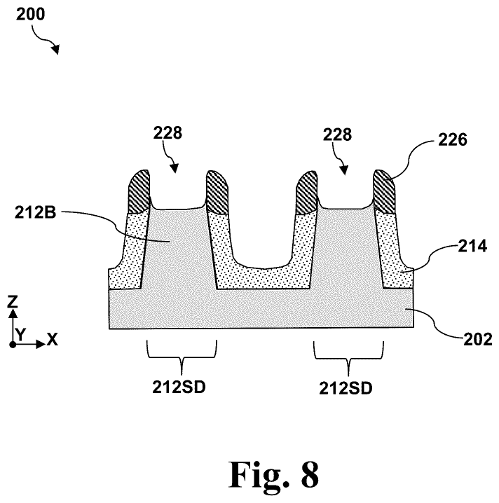

Referring to FIGS. 1, 7 and 8, method 100 includes a block 112 where a source/drain region 212SD of the fin-shaped structure 212 is anisotropically recessed to form a source/drain trench 228. The anisotropic etch may include a dry etch or a suitable etch process that etches the source/drain regions 212SD and a portion of the substrate 202. The resulting source/drain trench 228 extends vertically through the depth of the stack 204 and partially into the substrate 202. An example dry etch process for block 110 may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As illustrated in FIG. 7, the source/drain regions 212SD of the fin-shaped structure 212 are recessed to expose sidewalls of the sacrificial layers 206 and the channel layers 208. Because the source/drain trenches 228 extend below the stack 204 into the substrate 202, the source/drain trenches 228 include bottom surfaces and lower sidewalls defined in the substrate 202. Reference is made to FIG. 8, which includes a fragmentary cross-sectional view across two adjacent source/drain regions 212SD. As shown in FIG. 8, over the source/drain regions 212SD, the majority of the fin-shaped structure 212 is etched away and a top surface of the base fin structure 212B is exposed in the source/drain region 212SD. Because the gate spacer layer 226 etches at a slower rate than the fin-shaped structure 212, the gate spacer layer 226 in the source/drain region 212SD rises above the top surface of the base fin structure 212B.

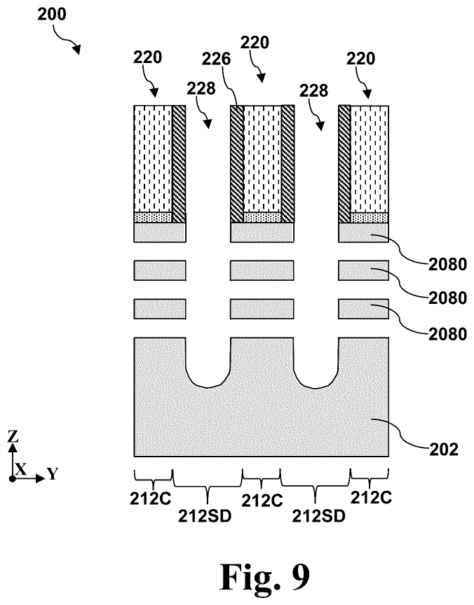

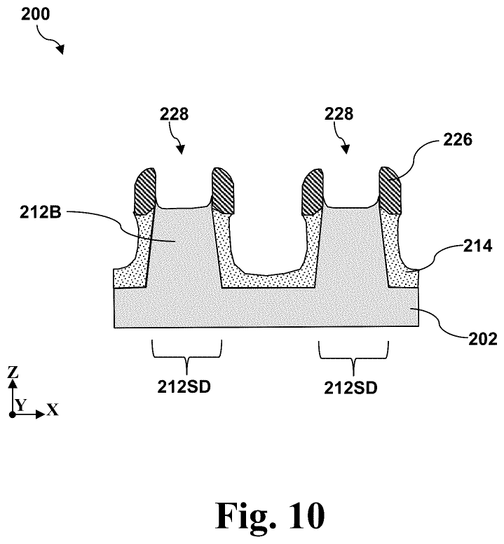

Referring to FIGS. 1, 9 and 10, method 100 includes a block 114 where the plurality of channel layers 208 in the channel regions are released as channel members 2080. After the formation of the source/drain trench 228, the sacrificial layers 206 interleaving the channel layers 208 in the channel region 212C are selectively removed. The selective removal of the sacrificial layers 206 releases the channel layers 208 (shown in FIG. 7) to form channel members 2080 shown in FIG. 9. The selective removal of the sacrificial layers 206 forms spaces between and around adjacent channel members 2080. The selective removal of the sacrificial layers 206 may be implemented by selective dry etch, selective wet etch, or a combination thereof. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture). Referring to FIG. 10. at block 116, the base fin structures 212B in the source/drain regions 212SD are not substantially etched. Depending on the design, the channel members 2080 may take form of nanowires, nanosheets, or other nanostructures.

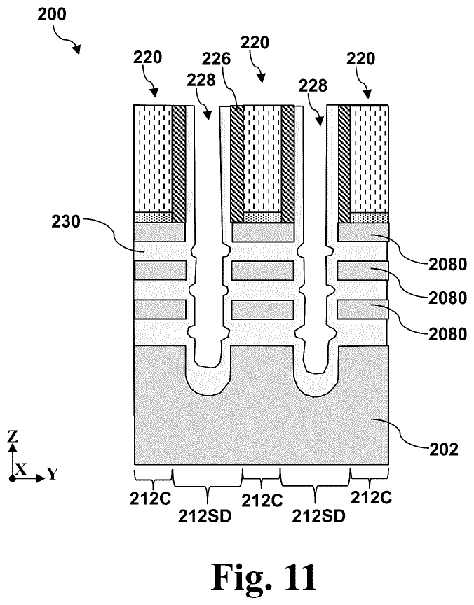

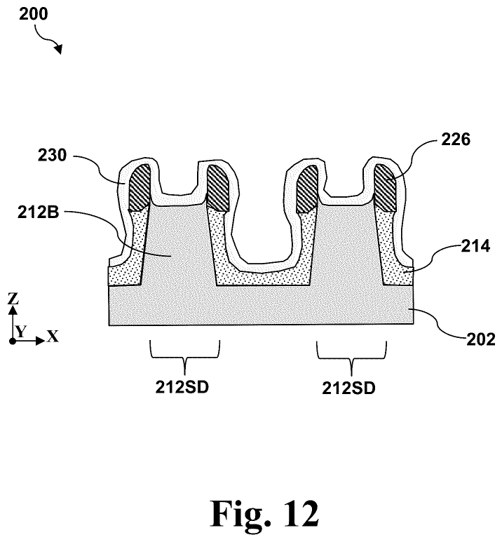

Referring to FIGS. 1, 11 and 12, method 100 includes a block 116 where a dummy layer 230 is deposited around the channel members 2080 and over the source/drain trenches 228. The dummy layer 230 may include silicon oxide and may be deposited using plasma enhanced chemical vapor deposition (PECVD) or ALD. As shown in FIG. 11, the dummy layer 230 fills the space among the channel members 2080 and covers end sidewalls of the channel members 2080. Additionally, the dummy layer 230 is in direct contact with a sidewall of the gate spacer layer 226 and a top surface of the substrate 202. Reference is made to FIG. 12, which includes a fragmentary cross-sectional view across two adjacent source/drain regions 212SD. As shown in FIG. 12, the dummy layer 230 extends conformally over the isolation feature 214, sidewalls of the gate spacer layer 226, and top surfaces of the gate spacer layer 226.

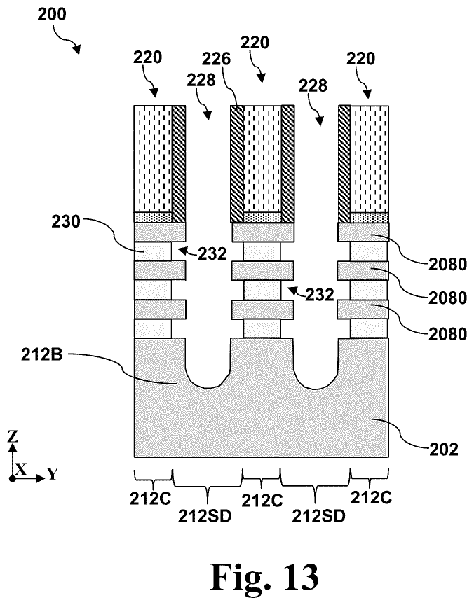

Referring to FIGS. 1 and 13, method 100 includes a block 118 where inner spacer recesses 232 are formed. Referring to FIG. 13, the dummy layers 230 are selectively and partially recessed to form inner spacer recesses 232 while the gate spacer layer 226, the dummy gate stack 220, the exposed portion of the substrate 202, and the channel layers 208 are substantially unetched. In an embodiment where the channel layers 208 consist essentially of silicon (Si) and the dummy layers 230 are formed of silicon oxide, the selective recess of the dummy layer 230 may be performed using a selective wet etch process or a selective dry etch process. An example selective dry etching process may include use of carbon tetrafluoride (CF₄), nitrogen trifluoride (NF₃), hydrogen (H₂), or a mixture thereof. An example selective wet etching process may include use of hydrofluoric acid, ammonium fluoride, or a mixture thereof.

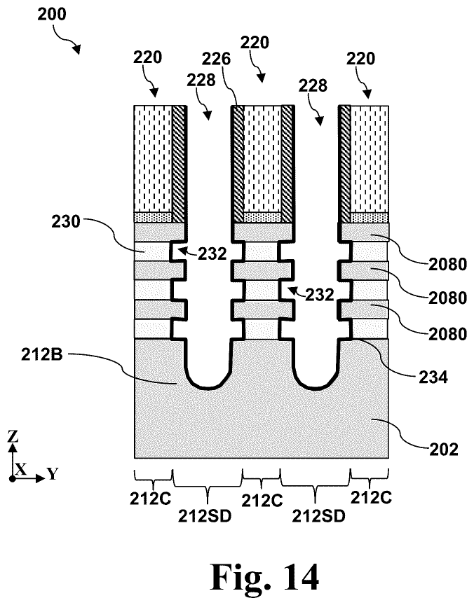

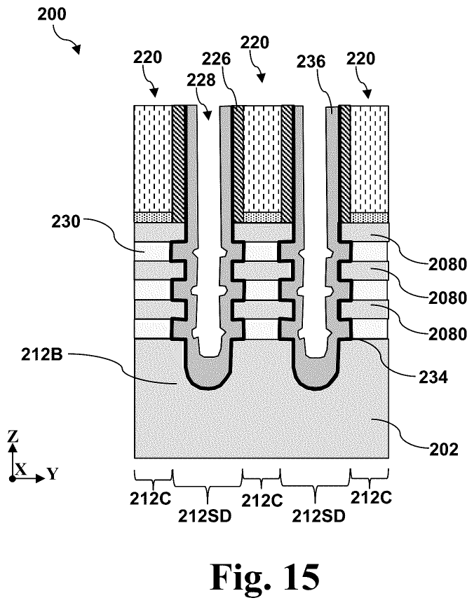

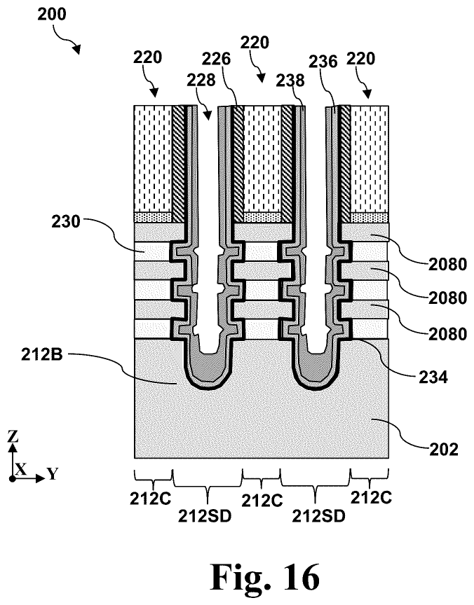

Referring to FIGS. 1, 14, 15, and 16, method 100 includes a block 120 where a plurality of inner spacer layers are deposited over the inner spacer recesses 232. In the depicted embodiments, the plurality of inner spacer layers may include two inner spacer layers—a first inner spacer layer 234 and a second inner spacer layer 236 illustrated in FIG. 15 or three inner layers—a first inner spacer layer 234, a second inner spacer layer 236 and a third inner spacer layer 238 illustrated in FIG. 16. It should be understood that additional inner spacer layers are fully envisioned. Reference is made to FIG. 14, which illustrates deposition of the first inner spacer layer 234. In some embodiments, the first inner spacer layer 234 is formed of a material that is substantially unetched when the dummy layers 230 is removed. That is, the first inner spacer layer 234 is formed of a material that allows the dummy layers 230 to be selectively removed. In some embodiments, the first inner spacer layer 234 includes silicon carbonitride, silicon nitride, silicon oxycarbonitride, silicon oxynitride, or silicon oxycarbide. As compared to a second inner spacer layer 236 (described below), the first inner spacer layer 234 may include more carbon (C), more nitrogen (N), or less oxygen (O). When the first inner spacer layer 234 includes carbon (C), a carbon content in the first inner spacer layer 234 may be between about 4% and about 30%. When the first inner spacer layer 234 includes nitrogen (N), a nitrogen content in the first inner spacer layer 234 may be between about 10% and about 40%. The additional carbon (C), additional nitrogen (N), or less oxygen (O) allows the first inner spacer layer 234 to be more resistant to etching chemistry that is directed to the dummy layer 230, which is formed of silicon oxide. Moreover, the additional carbon (C), additional nitrogen (N), or less oxygen (O) also give the first inner spacer layer 234 a greater dielectric constant. The removal of dummy layer 230 in a subsequent step may include use of hydrofluoric acid or hydrogen fluoride. It has been observed that the first inner spacer layer 234 may experience slow etching by hydrofluoric acid. The first inner spacer layer 234 may be deposited using atomic layer deposition (ALD). Before the removal of the dummy layer 230 in the subsequent step, a thickness of the first inner spacer layer 234 may be between about 1 nm and about 6 nm. In some instances, a dielectric constant of the first inner spacer layer 234 may be between about 3 and about 6.

FIG. 15 illustrates deposition of a second inner spacer layer 236 over the first inner spacer layer 234. Compared to the first inner spacer layer 234, the second inner spacer layer 236 has a lower dielectric constant to reduce parasitic capacitance. In some embodiments, the dielectric constant of the second inner spacer layer 236 may be between about 1.5 and 3.9. The second inner spacer layer 236 may have a thickness similar to that of the first inner spacer layer 234. In some embodiments, the thickness of the second inner spacer layer 236 may be between about 1 nm and about 5 nm. It should be noted that, in the final structure, a portion of the first inner spacer layer 234 is consumed when the channel members 2080 are released. As a result, in the final structure, the first inner spacer layer 234 is thinner than the second inner spacer layer 236 and has a thickness between about 0.1 nm and about 4.5 nm. The second inner spacer layer 236 is configured to have a low dielectric constant and is less etch resistant than the first inner spacer layer 234. In some embodiments, the second inner spacer layer 236 includes silicon carbonitride, silicon nitride, silicon oxycarbonitride, silicon oxynitride, or silicon oxycarbide. As compared to the first inner spacer layer 234, the second inner spacer layer 236 may include less carbon (C), less nitrogen (N), or more oxygen (O). When the second inner spacer layer 236 includes carbon (C), a carbon content in the second inner spacer layer 236 may be between about 0.1% and about 25%. When the second inner spacer layer 236 includes nitrogen (N), a nitrogen content in the second inner spacer layer 236 may be between about 0.1% and about 30%. The reduced carbon (C) content, reduced nitrogen (N) content, or additional oxygen (O) allows the second inner spacer layer 236 to provide reduced parasitic capacitance. The reduced carbon (C) content, reduced nitrogen (N) content, or additional oxygen (O) give the second inner spacer layer 236 a lower dielectric constant.

In some alternative embodiments, a third inner spacer layer 238 is deposited over the second inner spacer layer 236. While the second inner spacer layer 236 has a low dielectric constant to keep parasitic capacitance in check, it may be damaged during the etch back process to be described below. The third inner spacer layer 238 is deposited over the second inner spacer layer 236 to prevent undesirable loss of the second inner spacer layer 236. In order to serve its intended function, the third inner spacer layer 238 is more etch resistant than the second inner spacer layer 236 and has a dielectric constant greater than the dielectric constant of the second inner spacer layer 236. The third inner spacer layer 238 may include silicon carbonitride, silicon nitride, silicon oxycarbonitride, silicon oxynitride, or silicon oxycarbide. In some implementations, a composition of the third inner spacer layer 238 may be similar to that of the first inner spacer layer 234. In some alternative implementations, a composition of the third inner spacer layer 238 may fall between that of the first inner spacer layer 234 and that of the second inner spacer layer 236. When the third inner spacer layer 238 includes carbon, a carbon content of the third inner spacer layer 238 is greater than that of the second inner spacer layer 236 but smaller than that of the first inner spacer layer 234. When the third inner spacer layer 238 includes nitrogen, a nitrogen content of the third inner spacer layer 238 is greater than that of the second inner spacer layer 236 but smaller than that of the first inner spacer layer 234. When the third inner spacer layer 238 includes oxygen, an oxygen content of the third inner spacer layer 238 is greater than that of the first inner spacer layer 234 but smaller than that of the second inner spacer layer 236. In some embodiments, a thickness of the third inner spacer layer 238 may be between about 1 nm and about 5 nm. When the third inner spacer layer 238 and the first inner spacer layer 234 share the same composition, they may have the same dielectric constant. When the composition of the third inner spacer layer 238 falls between the first inner spacer layer 234 and the second inner spacer layer 236, its dielectric constant may also fall between the dielectric constant of the first inner spacer layer 234 and the second inner spacer layer 236.

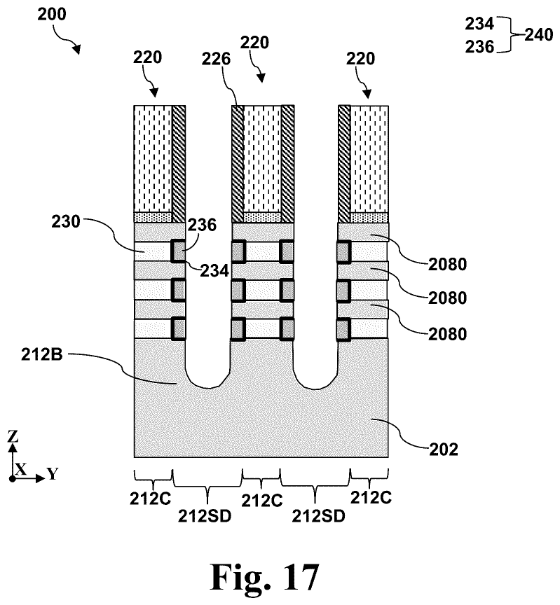

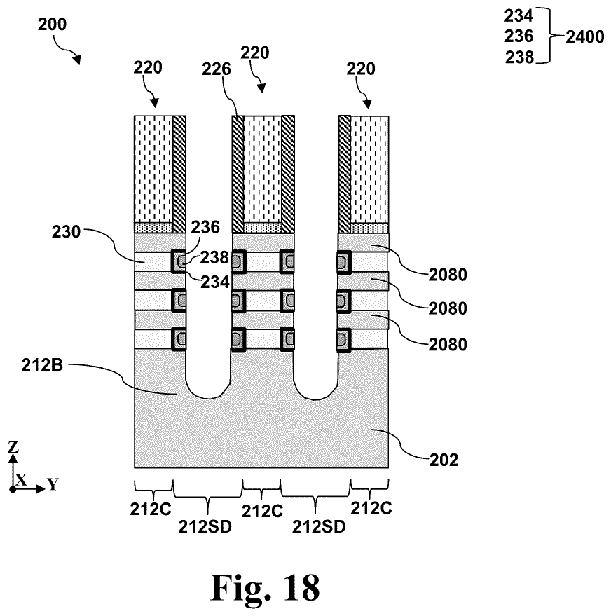

Referring to FIGS. 1, 17, 18, and 19, method 100 includes a block 122 where the plurality of inner spacer layers are etched back to form inner spacer features 240 over the inner spacer recesses 232. Referring to FIG. 17, the deposited first inner spacer layer 234 and second inner spacer layer 236 are then etched back to expose sidewalls of the channel members 2080, thereby forming inner spacer features 240 in the inner spacer recesses 232. Referring to FIG. 18, the deposited first inner spacer layer 234, second inner spacer layer 236 and the third inner spacer layer 238 are etched back to expose sidewalls of the channel members 2080, thereby forming inner spacer features 2400 in the inner spacer recesses 232. In some embodiments, the etching back at block 122 may include use of a dry etch process, such as a reactive ion etching (RIE) process that is aided by plasma. An example dry etch process may include use of boron trichloride (BCl₃), chlorine (Cl₂), hydrogen chloride (HCl), methane (CH₄), nitrogen trifluoride (NF₃), carbon tetrafluoride (CF₄), sulfur hexafluoride (SF₆), nitrogen (N₂), or a combination thereof. Referring to FIG. 17, each of the inner spacer features 240 is bilayer and includes the first inner spacer layer 234 and the second inner spacer layer 236. Referring to FIG. 18, each of the inner spacer features 2400 is tri-layer and includes the first inner spacer layer 234, the second inner spacer layer 236, and the third inner spacer layer 238.

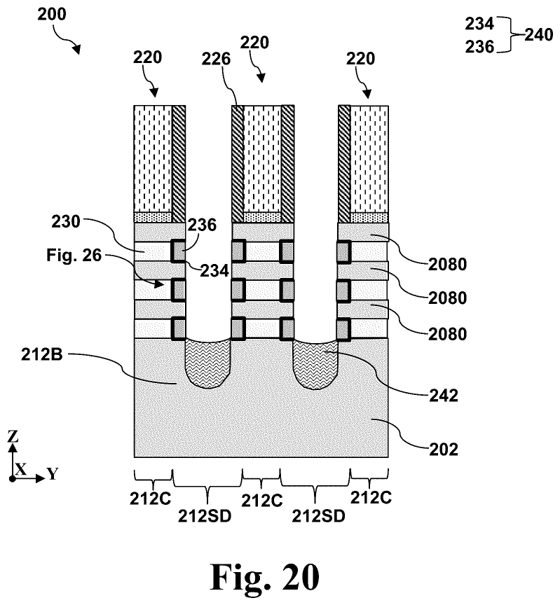

Referring to FIGS. 1 and 20, method 100 includes a block 124 where a bottom epitaxial layer 242 in the source/drain trench 228. In some embodiments, the bottom epitaxial layer 242 may include undoped silicon (Si) or undoped silicon germanium (SiGe). In an example process, a dielectric protective layer is conformally deposited over the source/drain trench 228 and an anisotropic etch process is performed to remove the bottom dielectric protective layer that covers the substrate 202 while the dielectric protective layer still covers sidewalls of the channel members 2080. With the exposed substrate 202 being the only exposed semiconductor surface, an epitaxial deposition process, such as VPE, UHV-CVD, or MBE, is used to selectively deposit the bottom epitaxial layer 242 on the exposed substrate 202 in the source/drain trench 228. After the deposition of the bottom epitaxial layer 242, the dielectric protective layer on the sidewalls of the source/drain recess 228 is selectively removed using a selective etch process. In the depicted embodiments, the bottom epitaxial layer 242 has a thickness such that a top surface of the bottom epitaxial layer 242 is substantially level with a bottom surface of the bottommost inner spacer feature 240. In other words, the top surface of the bottom epitaxial layer 242 is substantially level with a top surface of the base fin structure 212B.

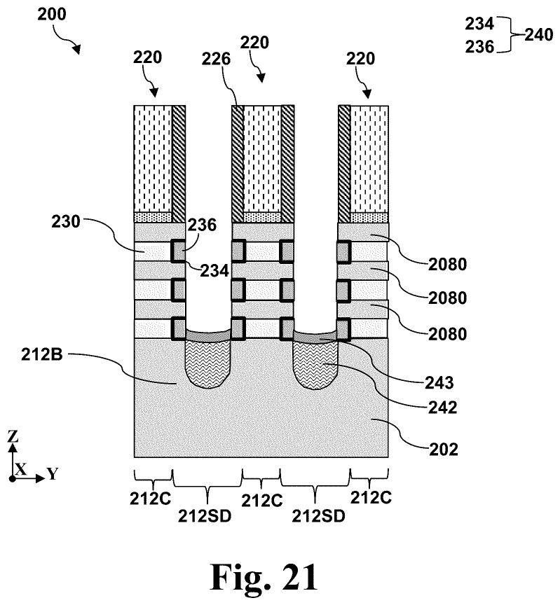

Referring to FIGS. 1 and 21, method 100 includes a block 126 where a bottom isolation layer 243 in the source/drain trench 228. Because the bottom isolation layer 243 may interface source/drain features and oxygen content may oxidize source/drain features, the bottom isolation layer 243 may be formed of an oxygen-free dielectric material, such as silicon nitride. In an example process, a chlorine-containing silicon nitride layer is deposited over the source/drain trench 228, including over a top surface of the bottom epitaxial layer 242. The chlorine-containing silicon nitride layer may be deposited using ammonia (NH₃) and a chlorine-containing silicon precursor, such as silicon tetrachloride (SiCl₄), dichlorodisilane (Si₂H₄Cl₂), dichlorosilane (SiH₂Cl₂), or hexachlorodisilane (Si₂Cl₆). The chlorine-containing silicon nitride layer may be deposited using plasma-enhanced atomic layer deposition (PEALD) or thermal ALD. A directional plasma treatment process is then performed to remove chlorine from a bottom portion of the chlorine-containing silicon nitride layer. In some embodiments, the directional plasma treatment may include use of an argon (Ar) plasma, a nitrogen (N₂) plasma, and/or a hydrogen (H₂) plasma. After the directional plasma treatment, a dry etch process using fluorine-containing etchant (e.g., trifluoromethane (CHF₃), nitrogen trifluoride (NF₃), hydrogen (H₂), ammonia (NH₃), carbon tetrafluoride (CF₄), or sulfur hexafluoride (SF₆)) may be performed. Because the dry etch process etches the chlorine-containing silicon nitride along sidewalls faster than it does relatively chlorine-free silicon nitride layer at the bottom of the source/drain trench 228, the bottom isolation layer 243 may be formed over the bottom epitaxial layer 242, as shown in FIG. 21. In some embodiments, the bottom isolation layer 243 may have a thickness between about 2.5 nm and about 6 nm. The bottom isolation layer 243 is in contact with the bottommost inner spacer feature 240 to form a leakage protection structure to insulate a source/drain feature 244 (to be described below) from the substrate 202.

Referring to FIGS. 1, 22 and 23, method 100 includes a block 128 where a source/drain feature 244 is formed over the source/drain region 212SD. While not explicitly shown, before any of the epitaxial layers are formed, method 100 may include a cleaning process to clean surfaces of the WIP structure 200. The cleaning process may include a dry clean, a wet clean, or a combination thereof. In some examples, the wet clean may include use of a mixture of deionized (DI) water, ammonium hydroxide, and hydrogen peroxide, a mixture of DI water, hydrochloric acid, and hydrogen peroxide), SPM (a sulfuric peroxide mixture), and or hydrofluoric acid for oxide removal. The dry clean process may include helium (He) and hydrogen (H₂) treatment. The hydrogen treatment may convert silicon on the surface to silane (SiH₄), which may be pumped out for removal.

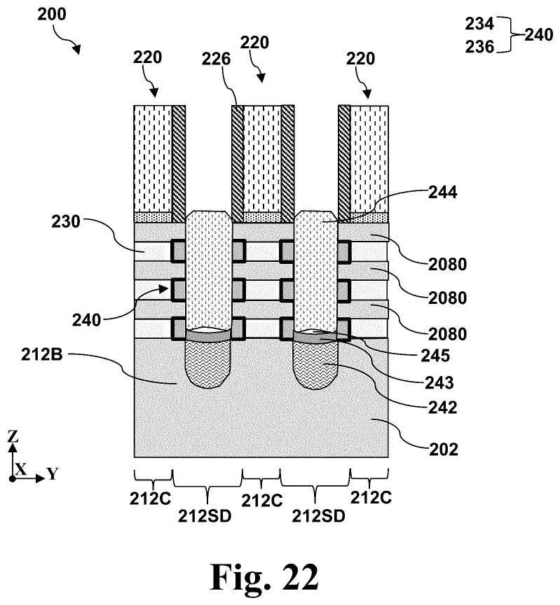

Reference is made to FIG. 22. The source/drain feature 244 may include more than one epitaxial layer and may be n-type or p-type. When the source/drain feature 244 is n-type, the more than one epitaxial layer in the source/drain feature may include silicon (Si) and an n-type dopant, such as phosphorus (P), arsenic (As), antimony (Sb), or a combination thereof. When the source/drain feature 244 is p-type, the more than one epitaxial layer may include silicon germanium (SiGe) and a p-type dopant, such as boron (B), boron difluoride (BF₂), or a combination thereof. The more than one epitaxial layer in the source/drain feature epitaxial layer(s) may include different dopant concentrations to reduce defects and resistance. The source/drain feature 244 may be formed using vapor-phase epitaxy (VPE), ultra-high vacuum CVD (UHV-CVD), or molecular beam epitaxy (MBE). Doping of the source/drain features 244 may be achieved with in-situ doping. The source/drain feature 244 interfaces sidewalls of the channel members 2080. In some embodiments, the source/drain feature 244 may merge over the inner spacer features 240 and the bottom isolation layer 243. In these embodiments, the source/drain feature 244 may contact inner spacer features 240 and the bottom isolation layer 243. In some alternative embodiments, the source/drain feature 244 may be at least partially spaced apart from the inner spacer features 240 and the bottom isolation layer 243 by a gap, such as the gap 245 between the source/drain feature 244 and the bottom isolation layer 243.

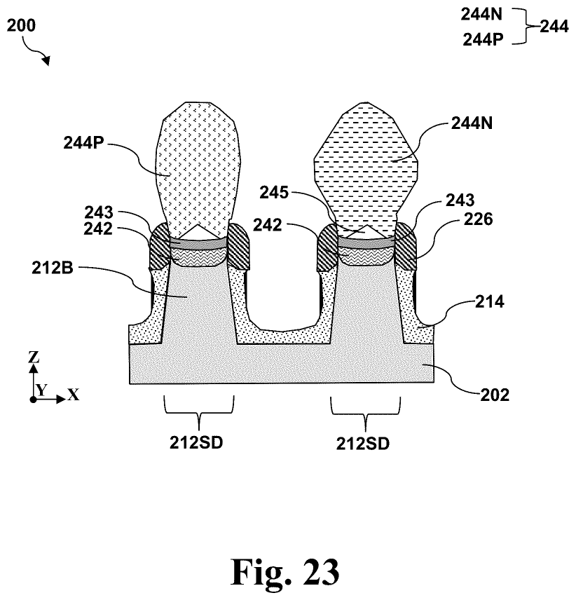

Reference is made to FIG. 23, which includes a fragmentary cross-sectional view across two adjacent source/drain regions 212SD. In some embodiments represented in FIG. 23, an n-type source/drain feature 244N may be adjacent a p-type source/drain feature 244P. The n-type source/drain feature 244N may include silicon (Si) and an n-type dopant, such as phosphorus (P), arsenic (As), or antimony (Sb). The p-type source/drain feature 244P may include silicon germanium (SiGe) and a p-type dopant, such as boron (B). Each of the n-type source/drain feature 244N and the p-type source/drain feature 244P may be in direct contact with a top surface of a base fin structure 212B and a sidewall of the gate spacer layer 226. For ease of illustration and description, the n-type source/drain feature 244N and the p-type source/drain feature 244P may be collectively referred to as the source/drain feature 244, as in FIG. 22.

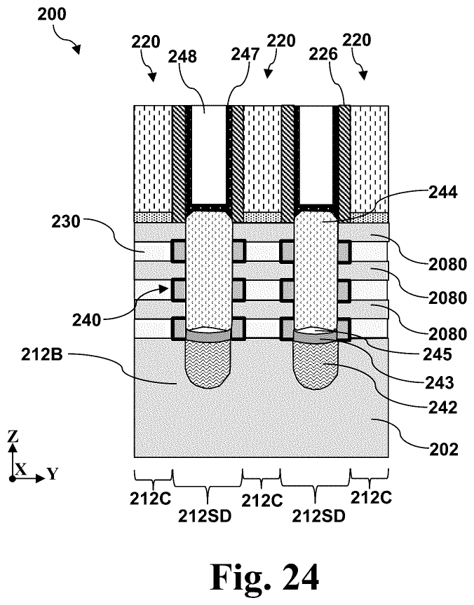

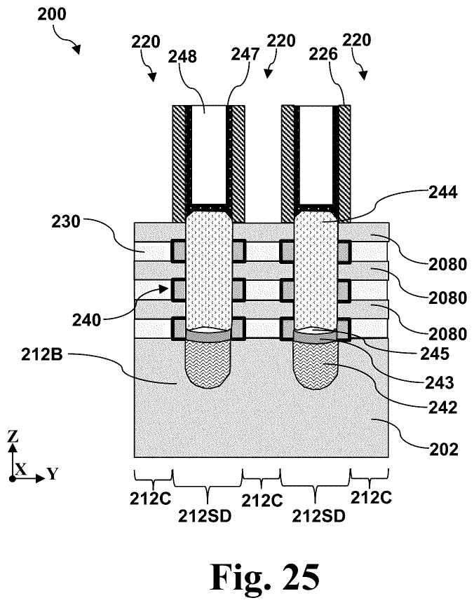

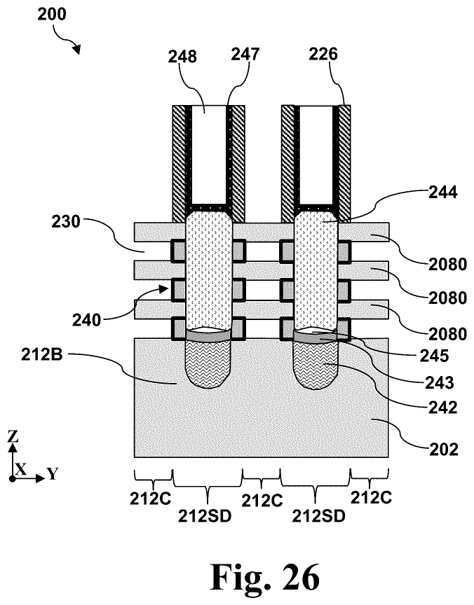

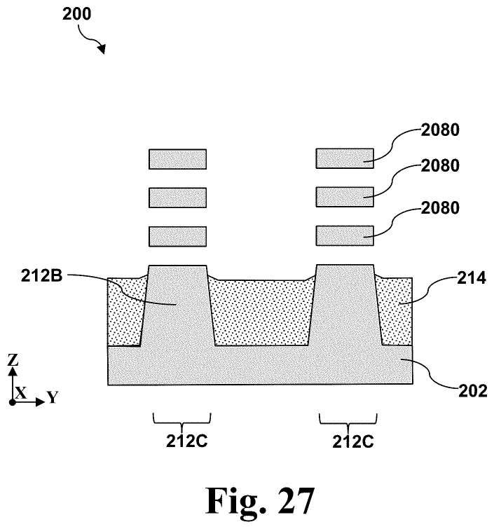

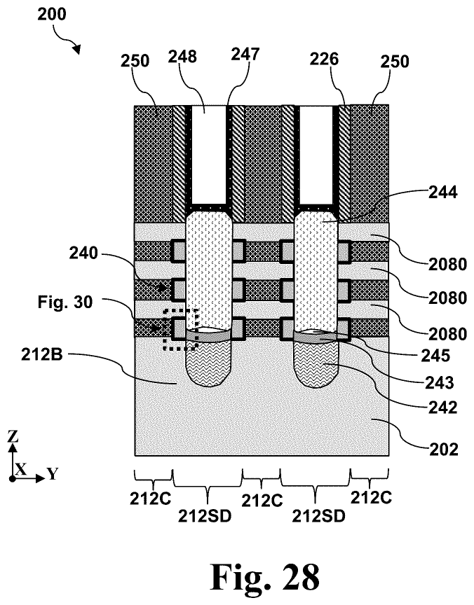

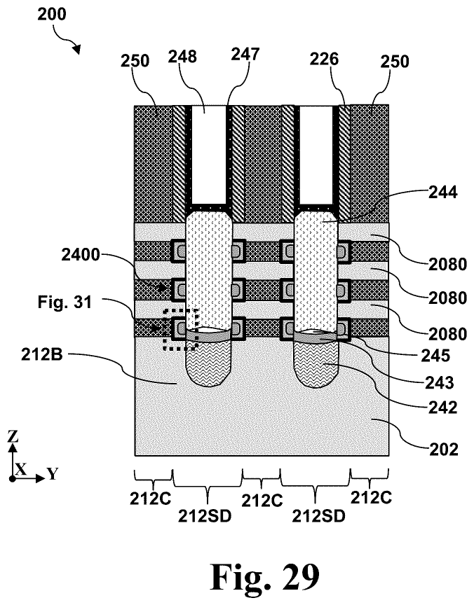

Referring to FIGS. 1 and 24-29, method 100 includes a block 130 where the dummy gate stack 220 and the dummy layer 230 are replaced with a gate structure 250. Operations at block 130 may include deposition of a contact etch stop layer (CESL) 247 over the source/drain features 244 (shown in FIG. 24), deposition of an interlayer dielectric layer 248 over the CESL 247 (shown in FIG. 24), removal of the dummy gate stack 220 (shown in FIG. 25), removal of the dummy layer 230 (shown in FIGS. 26 and 27), and deposition of the gate structure 250 to wrap around each of the channel members 2080 (shown in FIG. 28 and FIG. 29). Referring to FIG. 24, the CESL 247 is deposited over the WIP structure 200, including over the source/drain feature 244. The CESL 247 may include silicon nitride, silicon carbonitride or aluminum nitride. In some implementations, the CESL 247 may be deposited using CVD or atomic layer deposition (ALD). The ILD layer 248 is then deposited over the CESL 247. In some embodiments, the ILD layer 248 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 248 may be deposited using CVD, flowable CVD (FCVD), spin-on coating, or a suitable deposition technique. After the deposition of the ILD layer 248, the WIP structure 200 may be planarized by a planarization process to expose the dummy gate stack 220. For example, the planarization process may include a chemical mechanical planarization (CMP) process. Exposure of the dummy gate stack 220 allows the removal of the dummy gate stack 220. The removal of the dummy gate stack 220 may include one or more etching processes that are selective to the material of the dummy gate stack 220. For example, the removal of the dummy gate stack 220 may be performed using as a selective wet etch, a selective dry etch, or a combination thereof that is selective to the dummy gate stack 220.

After the removal of the dummy gate stack 220, the dummy layer 230 in the channel region 212C is exposed. A separate etch process may be performed to selectively remove the dummy layer 230 in the channel region 212C. For example, a selective wet etch process or a selective dry etch process may be performed to remove the dummy layer 230. An example selective wet etch process may include use of diluted hydrofluoric acid (DHF) or a mixture of hydrofluoric acid (HF) and, ammonium fluoride (NH₄F). An example selective dry etch process may include use of anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), or a combination thereof. As described above, the selective etch of the dummy layer 230 etches the first inner spacer layer 234 at a much smaller rate. After the selective removal of the dummy layer 230, the channel members 2080 in the channel region 212C are once again exposed as shown in FIGS. 26 and 27.

After the release of the channel members 2080, the gate structure 250 is formed to wrap around each of the channel members 2080 as shown in FIGS. 28 and 29. FIG. 28 illustrates an embodiment where the channel members 2080 are interleaved by inner spacer features 240, each of which includes the first inner spacer layer 234 and the second inner spacer layer 236. FIG. 29 illustrates an embodiment where the channel members 2080 are interleaved by inner spacer features 2400, each of which includes the first inner spacer layer 234, the second inner spacer layer 236, and the third inner spacer layer 238. While not explicitly shown, the gate structure 250 includes an interfacial layer interfacing the channel members 2080 and the substrate 202 in the channel region 212C, a gate dielectric layer over the interfacial layer, and a gate electrode layer over the gate dielectric layer. The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The gate dielectric layer may include a high-k dielectric material, such as hafnium oxide. Alternatively, the gate dielectric layer may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), combinations thereof, or other suitable material. The gate dielectric layer may be formed by ALD, physical vapor deposition (PVD), CVD, oxidation, and/or other suitable methods.

The gate electrode layer of the gate structure 250 may include a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer may be formed by ALD, PVD, CVD, e-beam evaporation, or other suitable process. In various embodiments, a CMP process may be performed to remove excessive metal, thereby providing a substantially planar top surface of the gate structure. The gate structure 250 includes portions that interpose between channel members 2080 in the channel region 212C. In some embodiments, the gate structure 250 may include a p-type gate structure portion and an n-type gate structure portion. The p-type gate structure portion includes p-type work function metal layers disposed closer to the channel members 2080. The n-type gate structure portion includes n-type work function metal layers disposed closer to the channel members 2080.

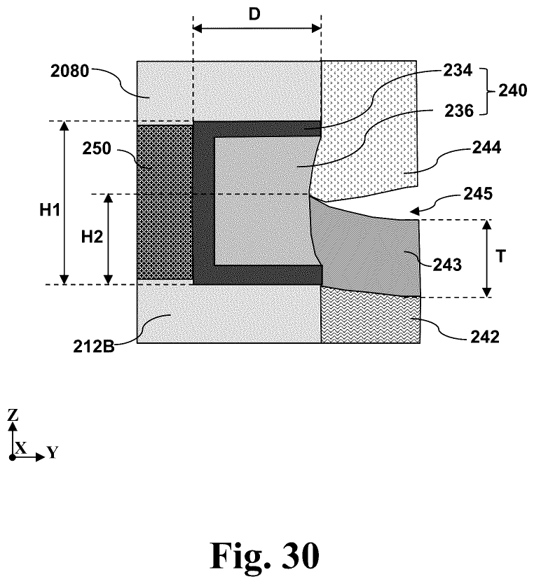

In the embodiment illustrated in FIG. 28, the gate structure 250 is spaced apart from the source/drain feature 244 by the inner spacer features 240. Each of the inner spacer features 240 in FIG. 28 includes the first inner spacer layer 234 and the second inner spacer layer 236. Each of the source/drain features 244 interface sidewalls of the channel members 2080. An area around a bottommost inner spacer feature 240 in FIG. 28 is enlarged and shown in FIG. 30. Referring to FIG. 30, the bottommost inner spacer feature 240 is vertically sandwiched between the base fin structure 212B and a bottommost channel member 2080. Along the channel length direction (i.e., Y direction), the bottommost inner spacer feature 240 is sandwiched between the gate structure 250 and the bottom isolation layer 243 as well as between the gate structure 250 and the source/drain feature 244. The source/drain feature 244 may span over and even contact the bottommost inner spacer feature 240. While the source/drain feature 244 may come in contact with the bottom isolation layer 243, the gap 245 may exist due to the selective epitaxial growth of the source/drain feature 244 from sidewall surfaces of the channel members 2080. In some embodiments represented in FIG. 30, the bottommost inner spacer feature 240 includes a depth D along the channel length direction (i.e., Y direction) and a first height H1 along the vertical direction (i.e., Z direction). The depth D may be between about 5 nm and about 10 nm and the first height H1 may be between about 5 nm and about 10 nm. The bottom isolation layer 243 may interface sidewalls of the first inner spacer layer 234 and the second inner spacer layer 236 of the inner spacer feature 240. In some embodiments, the bottom isolation layer 243 may include thickness T along the vertical direction. The thickness T may be between about 2.5 nm and about 5 nm. The interface between the bottom isolation layer 243 and the inner spacer feature 240 may define a second height H2. In some implementations, a ratio of the second height H2 to the first height H1 may be between about 0.2 and 0.8. This ratio is no trivial. When the ratio falls below 0.2, the shorter distance between the source/drain feature 244 and the base fin structure 212B may cause leakage concerns. When the ratio exceeds 0.8, the bottom isolation layer 243 may prevent the source/drain feature 244 from reaching a greater volume. Because a greater volume of the source/drain feature 244 leads to lower resistance, a higher H2/H1 ratio may lead increased resistance.

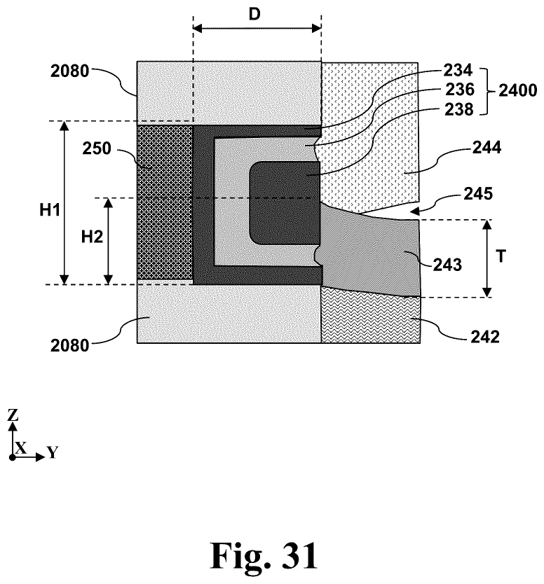

In the embodiment illustrated in FIG. 29, the gate structure 250 is spaced apart from the source/drain feature 244 by the inner spacer features 2400. In the embodiment illustrated in FIG. 29, the gate structure 250 is spaced apart from the source/drain feature 244 by the inner spacer features 2400. Each of the inner spacer features 2400 in FIG. 29 includes the first inner spacer layer 234, the second inner spacer layer 236, and the third inner spacer layer 238. Each of the source/drain features 244 interface sidewalls of the channel members 2080. An area around a bottommost inner spacer feature 240 in FIG. 29 is enlarged and shown in FIG. 31. Referring to FIG. 31, the bottommost inner spacer feature 2400 is vertically sandwiched between the base fin structure 212B and a bottommost channel member 2080. Along the channel length direction (i.e., Y direction), the bottommost inner spacer feature 2400 is sandwiched between the gate structure 250 and the bottom isolation layer 243 as well as between the gate structure 250 and the source/drain feature 244. The source/drain feature 244 may span over and even contact the bottommost inner spacer feature 240. While the source/drain feature 244 may come in contact with the bottom isolation layer 243, the gap 245 may exist due to the selective epitaxial growth of the source/drain feature 244 from sidewall surfaces of the channel members 2080. In some embodiments represented in FIG. 31, the bottommost inner spacer feature 2400 includes a depth D along the channel length direction (i.e., Y direction) and a first height H1 along the vertical direction (i.e., Z direction). The depth D may be between about 5 nm and about 10 nm and the first height H1 may be between about 5 nm and about 10 nm. The bottom isolation layer 243 may interface sidewalls of the first inner spacer layer 234, the second inner spacer layer 236, and the third inner spacer layer 238 of the inner spacer feature 2400. In some embodiments, the bottom isolation layer 243 may include thickness T along the vertical direction. The thickness T may be between about 2.5 nm and about 5 nm. The interface between the bottom isolation layer 243 and the inner spacer feature 2400 may define a second height H2. In some implementations, a ratio of the second height H2 to the first height H1 may be between about 0.2 and 0.8. This ratio is no trivial. When the ratio falls below 0.2, the shorter distance between the source/drain feature 244 and the base fin structure 212B may cause leakage concerns. When the ratio exceeds 0.8, the bottom isolation layer 243 may prevent the source/drain feature 244 from reaching a greater volume. Because a greater volume of the source/drain feature 244 leads to lower resistance, a higher H2/H1 ratio may lead increased resistance.

In one exemplary aspect, the present disclosure is directed to a semiconductor structure. The semiconductor structure includes a base fin over a substrate and including a first channel region, a second channel region, and a source/drain region between the first channel region and the second channel region, a first plurality of nanostructures disposed over the first channel region, a second plurality of nanostructures disposed over the second channel region, a first plurality of inner spacer features interleaving the first plurality of nanostructures, a second plurality of inner spacer features interleaving the second plurality of nanostructures, a bottom epitaxial layer over the source/drain region, a bottom isolation layer over the bottom epitaxial layer such that the bottom isolation layer interfaces a bottommost one of the first plurality of inner spacer features and a bottommost one of the second plurality of inner spacer features, and a source/drain feature disposed over the bottom isolation layer.

In some embodiments, each of the first plurality of inner spacer features and the second plurality of inner spacer features includes a plurality of inner spacer layers. In some implementations, the bottom isolation layer interfaces with sidewall of the plurality of inner spacer layers. In some instances, the plurality of inner spacer layers includes a first inner spacer layer and a second inner spacer layer, the first inner spacer layer and the second inner spacer layer include silicon, oxygen, nitrogen, and carbon, and an oxygen content of the second inner spacer layer is greater than an oxygen content of the first inner spacer layer. In some embodiments, the plurality of inner spacer layers includes a first inner spacer layer and a second inner spacer layer, the first inner spacer layer and the second inner spacer layer include silicon, oxygen, nitrogen, and carbon, and a nitrogen content of the first inner spacer layer is greater than a nitrogen content of the second inner spacer layer. In some embodiments, the plurality of inner spacer layers includes a first inner spacer layer and a second inner spacer layer, the first inner spacer layer and the second inner spacer layer include silicon, oxygen, nitrogen, and carbon, and a carbon content of the first inner spacer layer is greater than a carbon content of the second inner spacer layer. In some embodiments, the bottom isolation layer includes silicon nitride. In some instances, the bottom isolation layer includes a thickness, each of the first plurality of inner spacer features and the second plurality of inner spacer features includes a height, and a ratio of the thickness to the height is between about 0.4 and about 0.6. In some instances, the thickness is between about 2.5 nm and about 6 nm and the height is between about 5 nm and about 10 nm.

In another exemplary aspect, the present disclosure is directed to a semiconductor structure. The semiconductor structure includes a base fin over a substrate and including a channel region and a source/drain region adjacent the channel region, a plurality of nanostructures disposed over the channel region, a gate structure wrapping around each of the plurality of nanostructures, a plurality of inner spacer features interleaving the plurality of nanostructures, a bottom epitaxial layer over the channel region, a bottom isolation layer over the bottom epitaxial layer, and a source/drain feature disposed over the bottom isolation layer. Each of the plurality of inner spacer feature includes a first inner spacer layer interfacing the gate structure and a second inner spacer layer spaced apart from the gate structure by the first inner spacer layer and a sidewall of the bottom isolation layer interfaces the first inner spacer layer and the second inner spacer layer of a bottommost one of the plurality of inner spacer features.

In some embodiments, the first inner spacer layer and the second inner spacer layer comprise silicon, oxygen, nitrogen, and carbon and an oxygen content of the second inner spacer layer is greater than an oxygen content of the first inner spacer layer. In some embodiments, a carbon content of the first inner spacer layer is greater than a carbon content of the second inner spacer layer. In some embodiments, a nitrogen content of the first inner spacer layer is greater than a nitrogen content of the second inner spacer layer. In some implementations, the bottom isolation layer comprises a thickness, each of the plurality of inner spacer features comprises a height, and a ratio of the thickness to the height is between about 0.4 and about 0.6.

In yet another exemplary aspect, the present disclosure is directed to a method. The method includes forming over a substrate a stack that includes a plurality of channel layers interleaved by a plurality of sacrificial layers, patterning the stack and the substrate to form a fin-shaped structure having a base portion formed from the substrate and a stack portion formed from the stack, forming an isolation feature around the base portion, forming a dummy gate stack over a channel region of the fin-shaped structure, depositing a gate spacer layer over the dummy gate stack, after the depositing of the gate spacer layer, recessing a source/drain region of the fin-shaped structure to form a source/drain trench, selectively removing the plurality of sacrificial layers in the channel region to release the plurality of channel layers as a plurality of channel members, depositing a dummy layer over the plurality of channel members, selectively and partially recessing the dummy layer to form inner spacer recesses among the plurality of channel members, depositing a plurality of inner spacer layers over the inner spacer recesses, etching back the plurality of inner spacer layers to form inner spacer features in the inner spacer recesses, forming a bottom epitaxial layer over the source/drain trench, a top surface of the bottom epitaxial layer being substantially level with a bottom surface of a bottommost one of the inner spacer features, forming a bottom isolation layer on the bottom epitaxial layer such that a sidewall of the bottom isolation layer interfaces a sidewall of the bottommost one of the inner spacer features, forming a source/drain feature over the bottom isolation layer to interface sidewalls of the plurality of channel members, removing the dummy gate stack, removing the dummy layer, and forming a gate structure to wrap around each of the plurality of channel members.

In some embodiments, the bottom epitaxial layer includes undoped silicon or undoped silicon germanium. In some implementations, the bottom isolation layer includes silicon nitride. In some embodiments, the depositing of the plurality of inner spacer layers includes depositing a first inner spacer layer and depositing a second inner spacer layer over the first inner spacer layer. The first inner spacer layer and the second inner spacer layer include silicon, oxygen, nitrogen, and carbon and an oxygen content of the second inner spacer layer is greater than an oxygen content of the first inner spacer layer. In some embodiments, a carbon content of the first inner spacer layer is greater than a carbon content of the second inner spacer layer. In some embodiments, a nitrogen content of the first inner spacer layer is greater than a nitrogen content of the second inner spacer layer.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a base fin over a substrate and comprising a first channel region, a second channel region, and a source/drain region between the first channel region and the second channel region;
a first plurality of nanostructures disposed over the first channel region;
a second plurality of nanostructures disposed over the second channel region;
a first plurality of inner spacer features interleaving the first plurality of nanostructures;
a second plurality of inner spacer features interleaving the second plurality of nanostructures;
a bottom epitaxial layer over the source/drain region;
a bottom isolation layer over the bottom epitaxial layer such that the bottom isolation layer interfaces a bottommost one of the first plurality of inner spacer features and a bottommost one of the second plurality of inner spacer features; and
a source/drain feature disposed over the bottom isolation layer.

2. The semiconductor structure of claim 1, wherein each of the first plurality of inner spacer features and the second plurality of inner spacer features comprises a plurality of inner spacer layers.

3. The semiconductor structure of claim 2, wherein the bottom isolation layer interfaces with sidewall of the plurality of inner spacer layers.

4. The semiconductor structure of claim 2,
wherein the plurality of inner spacer layers comprises a first inner spacer layer and a second inner spacer layer,
wherein the first inner spacer layer and the second inner spacer layer comprise silicon, oxygen, nitrogen, and carbon,
wherein an oxygen content of the second inner spacer layer is greater than an oxygen content of the first inner spacer layer.

5. The semiconductor structure of claim 2,
wherein the plurality of inner spacer layers comprises a first inner spacer layer and a second inner spacer layer,
wherein the first inner spacer layer and the second inner spacer layer comprise silicon, oxygen, nitrogen, and carbon,
wherein a nitrogen content of the first inner spacer layer is greater than a nitrogen content of the second inner spacer layer.

6. The semiconductor structure of claim 2,
wherein the plurality of inner spacer layers comprises a first inner spacer layer and a second inner spacer layer,
wherein the first inner spacer layer and the second inner spacer layer comprise silicon, oxygen, nitrogen, and carbon,
wherein a carbon content of the first inner spacer layer is greater than a carbon content of the second inner spacer layer.

7. The semiconductor structure of claim 1, wherein the bottom isolation layer comprises silicon nitride.

8. The semiconductor structure of claim 1,
wherein the bottom isolation layer comprises a thickness,
wherein each of the first plurality of inner spacer features and the second plurality of inner spacer features comprises a height,
wherein a ratio of the thickness to the height is between about 0.4 and about 0.6.

9. The semiconductor structure of claim 8,
wherein the thickness is between about 2.5 nm and about 6 nm,
wherein the height is between about 5 nm and about 10 nm.

10. A semiconductor structure, comprising:
a base fin over a substrate and comprising a channel region and a source/drain region adjacent the channel region;
a plurality of nanostructures disposed over the channel region;
a gate structure wrapping around each of the plurality of nanostructures;
a plurality of inner spacer features interleaving the plurality of nanostructures;
a bottom epitaxial layer over the channel region;
a bottom isolation layer over the bottom epitaxial layer; and
a source/drain feature disposed over the bottom isolation layer,
wherein each of the plurality of inner spacer feature includes a first inner spacer layer interfacing the gate structure and a second inner spacer layer spaced apart from the gate structure by the first inner spacer layer,
wherein a sidewall of the bottom isolation layer interfaces the first inner spacer layer and the second inner spacer layer of a bottommost one of the plurality of inner spacer features.

11. The semiconductor structure of claim 10,
wherein the first inner spacer layer and the second inner spacer layer comprise silicon, oxygen, nitrogen, and carbon,
wherein an oxygen content of the second inner spacer layer is greater than an oxygen content of the first inner spacer layer.

12. The semiconductor structure of claim 11,
wherein a carbon content of the first inner spacer layer is greater than a carbon content of the second inner spacer layer.

13. The semiconductor structure of claim 11,
wherein a nitrogen content of the first inner spacer layer is greater than a nitrogen content of the second inner spacer layer.

14. The semiconductor structure of claim 11,
wherein the bottom isolation layer comprises a thickness,
wherein each of the plurality of inner spacer features comprises a height,
wherein a ratio of the thickness to the height is between about 0.4 and about 0.6.

15. A method, comprising:
forming over a substrate a stack that includes a plurality of channel layers interleaved by a plurality of sacrificial layers;
patterning the stack and the substrate to form a fin-shaped structure having a base portion formed from the substrate and a stack portion formed from the stack;
forming an isolation feature around the base portion;
forming a dummy gate stack over a channel region of the fin-shaped structure;
depositing a gate spacer layer over the dummy gate stack;
after the depositing of the gate spacer layer, recessing a source/drain region of the fin-shaped structure to form a source/drain trench;
selectively removing the plurality of sacrificial layers in the channel region to release the plurality of channel layers as a plurality of channel members;
depositing a dummy layer over the plurality of channel members;
selectively and partially recessing the dummy layer to form inner spacer recesses among the plurality of channel members;
depositing a plurality of inner spacer layers over the inner spacer recesses;
etching back the plurality of inner spacer layers to form inner spacer features in the inner spacer recesses;
forming a bottom epitaxial layer over the source/drain trench, a top surface of the bottom epitaxial layer being substantially level with a bottom surface of a bottommost one of the inner spacer features;
forming a bottom isolation layer on the bottom epitaxial layer such that a sidewall of the bottom isolation layer interfaces a sidewall of the bottommost one of the inner spacer features;
forming a source/drain feature over the bottom isolation layer to interface sidewalls of the plurality of channel members;
removing the dummy gate stack;
removing the dummy layer; and
forming a gate structure to wrap around each of the plurality of channel members.

16. The method of claim 15, wherein the bottom epitaxial layer comprises undoped silicon or undoped silicon germanium.

17. The method of claim 15, wherein the bottom isolation layer comprises silicon nitride.

18. The method of claim 15,
wherein the depositing of the plurality of inner spacer layers comprises:
depositing a first inner spacer layer, and
depositing a second inner spacer layer over the first inner spacer layer, and
wherein the first inner spacer layer and the second inner spacer layer comprise silicon, oxygen, nitrogen, and carbon, and
wherein an oxygen content of the second inner spacer layer is greater than an oxygen content of the first inner spacer layer.

19. The method of claim 18, wherein a carbon content of the first inner spacer layer is greater than a carbon content of the second inner spacer layer.

20. The method of claim 18, wherein a nitrogen content of the first inner spacer layer is greater than a nitrogen content of the second inner spacer layer.
